(19) United States
(12) Patent Application Publication
(10) Pub. No.: US 2008/0116932 A1
(43) Pub. Date: May 22, 2008

(54) STRUCTURED ASIC LAYOUT ARCHITECTURE HAVING TUNNEL WIRES

(75) Inventors: CHANG-YU WU, TAINAN COUNTY (TW); MING-HSIN KU, HSINCHU CITY (TW); SHANG-CHIH HSIEH, KAOHSIUNG COUNTY (TW); HSIN-SHIH WANG, FREMONT, CA (US)

Correspondence Address: J C PATENTS, INC., 4 VENTURE, SUITE 250, IRVINE, CA, 92618, US

(73) Assignee: FARADAY TECHNOLOGY CORP., HSINCHU (TW)

(21) Appl. No.: 11/560,518

(22) Filed: Nov. 16, 2006

(51) Int. Cl. H03K 19/173; H03K 19/00

(52) U.S. Cl. 326/47; 326/102

(57) ABSTRACT

The present invention discloses a structured ASIC layout architecture, which includes a fixed body region and a programmable layout region. The fixed body region includes a tunnel wire or multiple tunnel wires for providing a function capability or multiple function capability. The programmable layout region is disposed on the fixed body region and is connected to the fixed body region, wherein the programmable layout region utilizes the tunnel wires of the fixed body region to propagate electrical signals.

### BACKGROUND OF THE INVENTION

1. Field of the Invention

The present invention relates to a structured ASIC layout architecture, and more particularly, to a structured ASIC layout architecture having tunnel wires.

2. Description of the Related Art

Along with the development of the nano-dimension scale in the semiconductor process and the complexity of the SoC (system on chip) technology in the circuit design, circuit design verification gradually becomes one of the key factors that will affect the schedule of R&D. In the circuit design, some steps such as trial chip verification, prototype fabrication and production yield forecast will be carried out first, so as to justify mask cost. However, the cost of the mask correspondingly increases as the manufacturing process moves toward minimization day by day. After a circuit has been designed, several steps of verification and modification are needed, which may require revision or improvement of the related hardware, resulting in an increase of the cost of the masks in the fabrication. If the circuit design is improper, not only the cost of the masks is considerably wasted, but also the time on design is increased. For chip design, the cost of the masks and various related designs is very high. Thus, how to lower the R&D cost and shorten the development period is an important issue to cope with the nano-scale age.

The so-called structured ASIC (application specific integrated circuit) is a method derived in consideration of the disadvantages described above. In the method, an intellectual property (IP) element is embedded in the wafer, so that a chip is developed through a customized design and has fewer metal layers. Compared with a full set of masks and the conventional design methodology, the structured ASIC is able to largely save the mask cost. Since the programmable implementation is based on masks, therefore, comparatively fewer layers of masks can achieve the programmable implementation goal with an acceptable cost. As only fewer masks are to be customized, the manufacturing period of a chip is accordingly shortened and the fabrication cost is reduced. Moreover, since a non-programmable portion of the IC chip, i.e. a couple of mask layers, has a uniform and universal layout, hence the analogous circuits can share the non-programmable mask layers for implementation at a less cost. Therefore, some circuit designs without much economic profit can adopt the advanced processing technology.

In terms of the technology where fewer masks are used to change the function of manufactured ICs, the programmable layers, i.e. the upper layers thereof, are used for changing the cell functions and the routes to meet the requirement of a customer's need, while the lines in the cells and the lines between the cells share a limited routing resource. In the prior art, the lines in the cells are used to connect a P-type metal oxide semiconductor (P-type MOS region) and an N-type metal oxide semiconductor (N-type MOS region) to realize a CMOS (complementary metal oxide semiconductor) transistor pair function. In U.S. Pat. No. 5,923,059, an IC unit architecture and the routing method thereof are disclosed. The unit architecture is shown by FIG. 1, where a P-type MOS region 11 and an N-type MOS region 12 are connected to each other by a metal wire 13 for propagating electrical signals, the P-type MOS region 11 is connected a power voltage VCC through a metal wire 14 and the N-type MOS region 12 is connected a grounding voltage GND through a metal wire 15. It is noted that the routing scheme of the metal wire 13 herein needs an area over the P-type MOS region 11 and the N-type MOS region 12 to be occupied, i.e. by using some of the upper metal layers would lower the routing resource, thereby remarkably decrease the routability and increase the cost.

FIG. 2 is a layout architecture diagram of another conventional IC unit. Wherein, a P-type MOS region 21 and a P-type MOS region 23 are connected to each other via a metal wire 24, and the P-type MOS region 21 and an N-type MOS region 22 are connected to each other via a metal wire 25. In order to connect a transistor T21 and a transistor T22 together via the metal wire 25, the metal wire 25 must routed/passed through a space over the metal wire 24 due to the intersecting routing of the metal wires 24 and 25, and therefore causing a blocking effect due to the layout space limitation. In order to minimize the layout area herein, a metal wire occupying a part of the layout space would conflict with and squeeze out other designs within the layout.

The U.S. Pat. No. 6,617,621 discloses a gate array architecture with elevated metal layers, as shown by FIG. 3. Wherein, a node 311 of a P-type MOS region 31 and a node 321 of an N-type MOS region 32 are connected to each other in fixed connection manner via a metal wire 33. Even though the fixed connection manner is able to simplify the connection, but limits the functionalities and renders the design less flexible.

### SUMMARY OF THE INVENTION

An objective of the present invention is to provide a structured ASIC layout architecture having tunnel wires, which is capable of saving cost, providing a simple circuit connection scheme, saving routing resource of the programmable layout region reserved for a customer's user end to tailor and improve the routability.

Another objective of the present invention is to provide a structured ASIC layout architecture having tunnel wires, which is capable of providing a simple circuit connection scheme for connecting multiple transistors to save cost, saving routing resource of the programmable layout region reserved for a customer's user end to tailor and improve the routability.

The present invention provides a structured ASIC layout architecture having tunnel wires, which includes a fixed body region and a programmable layout region. The fixed body region is adopted for providing a single function capability or multiple function capability. The fixed body region includes a single tunnel wire or multiple tunnel wires used for providing reserve connection paths. The programmable layout region is disposed on the fixed body region and connected to the fixed body region for providing function capability, wherein the programmable layout region is connected to the tunnel wires of the fixed body region, so as to start up the reserve connection paths for propagating electrical signals.

According to an embodiment of the present invention, in the above-described structured ASIC layout architecture includes a first metal layer and the programmable layout region includes a programmable via layer and is connected to the metal layers of the tunnel wires via the programmable via layer.

According to an embodiment of the present invention, the tunnel wire in the above-described structured ASIC layout architecture further includes a second metal layer and a via layer, and the programmable layout region includes a programmable metal layer, wherein the programmable layout region is connected to the via layer of the tunnel wire via the programmable metal layer.

According to an embodiment of the present invention, in the above-described structured ASIC layout architecture, the tunnel wires of the fixed body region are isolated from other devices of the fixed body region.

The present invention provides a structured ASIC layout architecture having tunnel wires, which includes a fixed body region and a programmable layout region. The fixed body region is adopted for providing a single function capability or multiple function capability. The fixed body region includes a single tunnel wire or multiple tunnel wires for serving reserve connection paths. The programmable layout region is disposed on the fixed body region and connected to the fixed body region for providing function capability, wherein the programmable layout region is connected to the tunnel wires of the fixed body region, so as to start up the reserve connection paths for the transistors to propagate electrical signals thereby.

According to the embodiment of the present invention, in the structured ASIC layout architecture having tunnel wires, the tunnel wires of the fixed body region are isolated from other devices of the fixed body region.

Since the present invention adopts a structure where the programmable layout region is adopted to propagate an electrical signal by using a tunnel wire of the fixed body region, and therefore it is possible to save cost and the routing resource of the programmable layout region reserved for a customer's user end to tailor, and simplify the circuit connection scheme and improve the routability in a chip.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a layout diagram of a conventional IC unit architecture and the routing method thereof.

FIG. 2 is a layout diagram of another conventional IC unit architecture and the routing method thereof.

FIG. 3 is a layout diagram of a conventional gate array architecture with elevated metal layers.

FIG. 4 is a schematic cross-sectional drawing of a structured ASIC layout architecture according to an embodiment of the present invention.

FIG. 5A is a diagram of a structured ASIC layout architecture according to an embodiment of the present invention.

FIG. 5B is a schematic cross-sectional drawing of the tunnel wire according to an embodiment of the present invention.

FIG. 6 is a schematic cross-sectional drawing of a structured ASIC layout architecture according to another embodiment of the present invention.

FIG. 7 is a schematic cross-sectional drawing of the tunnel wire according to another embodiment of the present invention.

FIG. 8 is a diagram of a structured ASIC layout architecture according to another yet embodiment of the present invention.

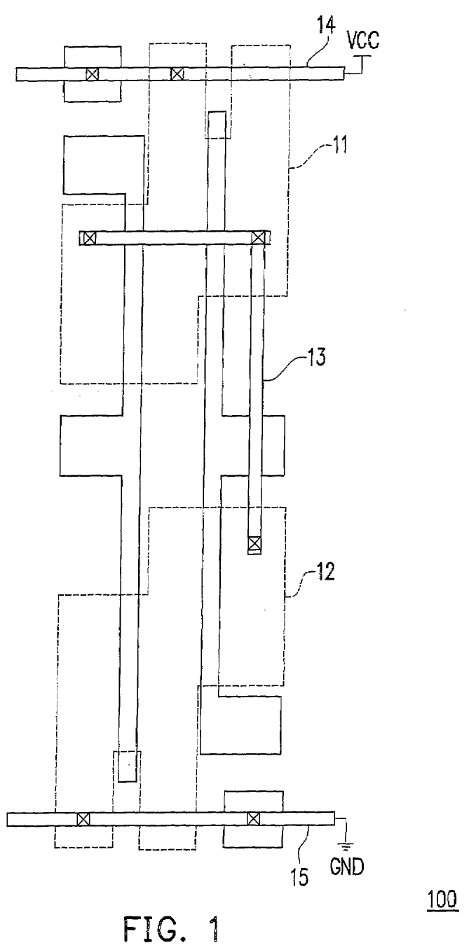

### DESCRIPTION OF THE EMBODIMENTS

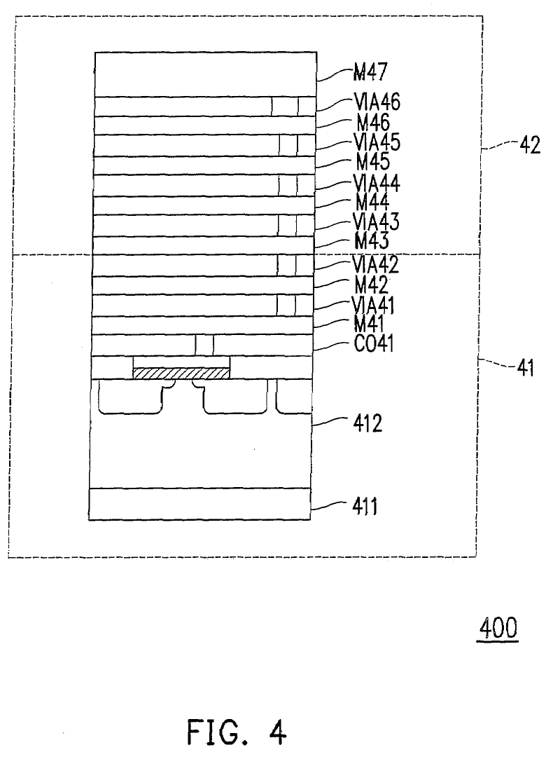

FIG. 4 is a schematic cross-sectional drawing of a structured ASIC layout architecture 400 according to an embodiment of the present invention, wherein structured ASIC layout architecture 400 includes tunnel wires and requires comparatively fewer number of masks for fabrication. The structured ASIC 400 includes a fixed body region 41 and a programmable layout region 42. The fixed body region 41 includes metal layers M41 and M42, via layers VIA41 and VIA42, a via contact layer CO41, a device region 412 and a substrate 411. The fixed body region 41 is, in association with the programmable layout region 42, used to provide a function capability or multiple function capability, such as the circuit operation or the phase-inverting signals. The device region 412 includes multiple circuit devices, such as P-type MOS transistors and P-type MOS transistors and is located on the substrate 411. The metal layer 41 is connected to the device region 412 through the via contact layer CO41, while the metal layer M42 is respectively connected to the metal layer 41 through the via layer VIA41 and to the programmable layout region 42 through the via layer VIA42. The fixed body region 41 is a fixed and un-programmable part.

The programmable layout region 42 is disposed on the fixed body region 41 and includes programmable metal layers M43˜M47 and programmable via layers VIA43˜VIA46, wherein the programmable metal layers M43˜M47 and the programmable via layers VIA43˜VIA46 can be designed to meet a specific requirement, are connected to the fixed body region 41 and may be used for different functions according to the different requirements. The fixed body region includes a tunnel wire or multiple tunnel wires (not shown), the metal layer M42 and the via layer VIA42. By using the tunnel wires of the fixed body region 41, the programmable layout region 42 is able to propagate an electrical signal, which saves the layout space of the programmable layout region 42.

With the finite mask technique, the number of layout layers in the programmable layout region 42 is limited, therefore, too dense wiring in the programmable layout region 42 would seriously consume the layout space. To solve the problem, the present invention utilizes the tunnel wires disposed in the fixed body region 41, so that the programmable layout region 42 is able to propagate electrical signals through the tunnel wires of the fixed body region 41 for saving cost and the routing resource of the programmable layout region 42.

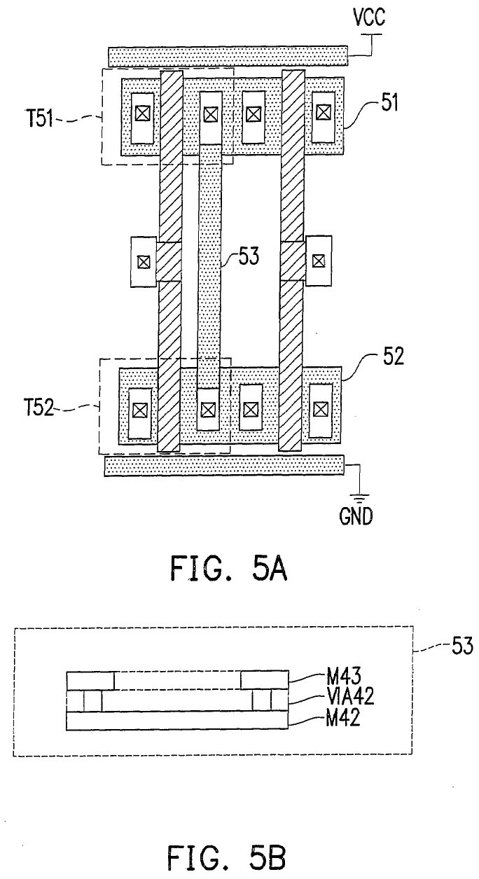

FIG. 5A is a diagram of the structured ASIC layout architecture 400 having tunnel wires according to an embodiment of the present invention. A transistor T51 of a P-type MOS transistor 51 and a transistor T52 of an N-type MOS transistor are connected to each other through a tunnel wire 53. Referring to FIGS. 4 and 5A, the tunnel wire with linear (straight line) shape 53 is disposed in advance in the fixed body region 41 according to a design, which provides a reserve interconnection path available for the programmable layout region 42 to propagate electrical signals between the P-type MOS transistor 51 and the N-type MOS transistor 52 depending on the need. The tunnel wire 53 is disposed for saving the layout space of the programmable layout region and simplifying routing; thus, to optimize the disposition thereof, the most possible placement and allocation in the programmable layout region 42 is chosen in advance based on the development experience. In order to be isolated from other devices in the fixed body region 41, the tunnel wire 53 in the fixed body region 41 is floated, and the programmable layout region 42 would decide how to utilize the tunnel wire 53 depending on a customer's user end in future. Although the tunnel wire in the embodiment has, but not limited by the present invention, a linear (straight line) shape, however one skilled the art can design the tunnel wire into other shapes, for example, a polygonal curve shape or a curve shape.

FIG. 5B is a schematic cross-sectional drawing of the tunnel wire 53 according to an embodiment of the present invention. Referring to FIGS. 4 and 5B, the tunnel wire 53 includes a metal layer 43 of the programmable layout region 42, a via layer VIA42 of the fixed body region 41 and a metal layer M42 of the fixed body region 41. The metal layer M43 of the programmable layout region 42 is connected to the tunnel wire 53. The tunnel wire 53 provides a spare interconnection path, and the programmable layout region 42 is connected to the tunnel wire 53 of the fixed body region 41 through the metal layer M43, so as to start up the reserve interconnection path to propagate an electrical signal at a subsequent stage.

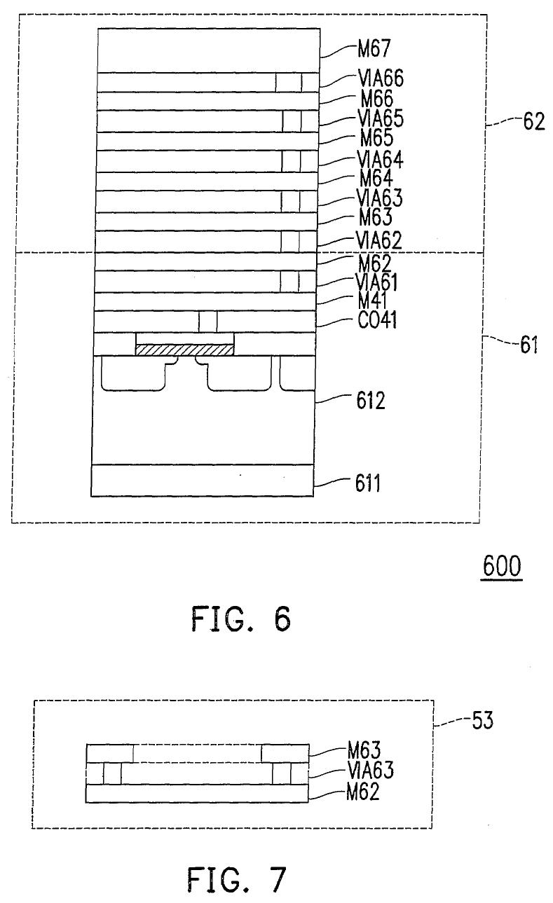

FIG. 6 is a schematic cross-sectional drawing of a structured ASIC layout architecture 600 according to another embodiment of the present invention. The structured ASIC layout architecture 600 includes a fixed body region 61 and a programmable layout region 62, wherein the fixed body region 61 includes a substrate 611, a device region 612, a via contact layer CO61, metal layers M61 and M62 and a via layer VIA61. The programmable layout region 62 includes metal layers M63˜M67 and via layers VIA62˜VIA66. In contrast to the above-described embodiment, the fixed body region 61 herein is connected to the via layer VIA 62 of the programmable layout region 62 through the metal layer M62. The tunnel wire 53 provides a reserve interconnection path, and the programmable layout region 62 is connected to the tunnel wire 53 of the fixed body region 41 through the via layer VIA62, so as to start up the reserve interconnection path to propagate an electrical signal at the subsequent stage.

FIG. 7 is a schematic cross-sectional drawing of the tunnel wire 53 according to another embodiment of the present invention. Referring to FIGS. 5A, 6 and 7, the tunnel wire 53 includes a metal layer M63 of the programmable layout region 62, a via layer VIA62 of the programmable layout region 62 and a metal layer M62 of the fixed body region 61. In contrast to the above-described embodiments, the programmable layout region 62 is connected to the tunnel wire 53 through the metal layer M63 and the via layer VIA62, and in the present embodiment, the tunnel wire 53 occupies more space in the programmable layout region 62, but less space in the fixed body region 61.

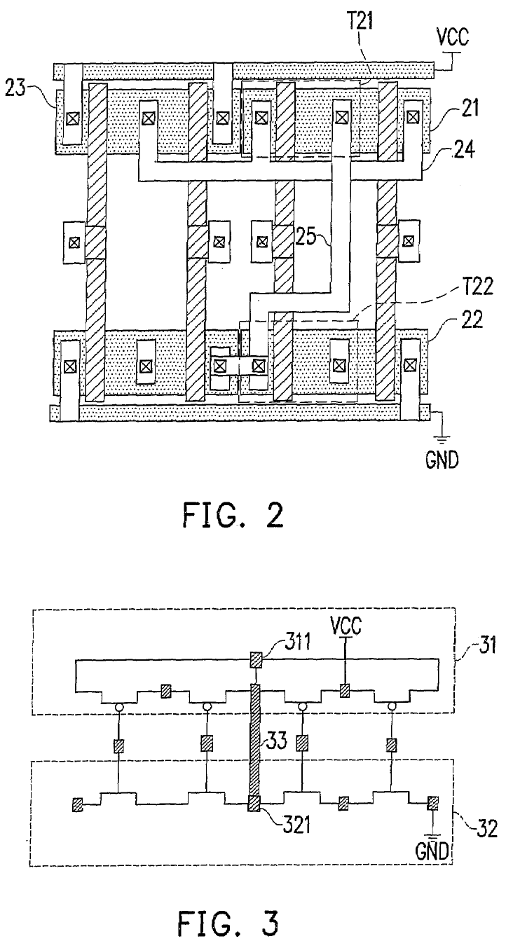

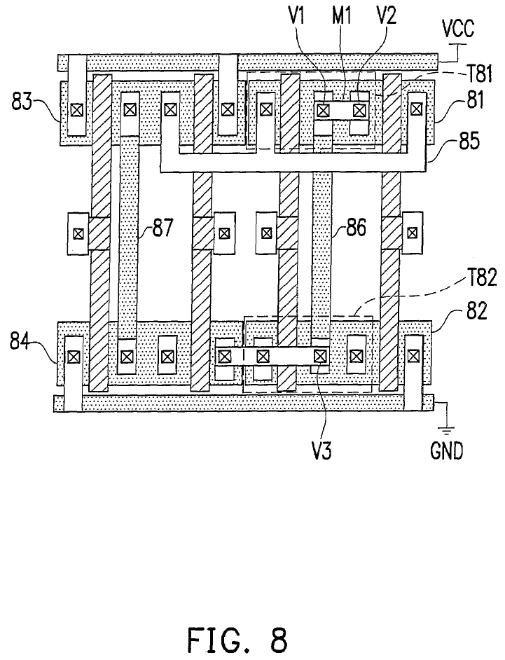

The tunnel wire of the present invention can serve as an interconnect line between the cells or an internal interconnect line of a cell and the tunnel wire placement is predetermined in the space of the fixed body region, so as to save the space of the programmable layout region. FIG. 8 is a diagram of a structured ASIC layout architecture according to another yet embodiment of the present invention. The circuit function implemented by the embodiment is the same as the conventional IC unit shown in FIG. 2. Referring to FIGS. 2 and 8, the metal wire 25 in FIG. 2 is replaced by a tunnel wire 86 of FIG. 8. A P-type MOS region 81 is connected to an N-type MOS region 82 for propagating electrical signals through the tunnel wire 86, a P-type MOS region 83 is connected to an N-type MOS region 84 for propagating electrical signals through a tunnel wire 87, a P-type MOS region 81 is connected to a P-type MOS region 83 through a metal wire 85 and a transistor T81 is connected to a transistor T82 through the tunnel wire 86. Since the tunnel wire 86 is planned in advance, thus, the transistor T81 is connected to a via V1 in a doped region though a via V2 in the doped region and a metal wire M1. Next, the via V2 is connected to the via V3 of a transistor T82 through the tunnel wire 86. It can be seen therefrom, the tunnel wire 86 is disposed in the fixed body region, while the metal wire 85 is disposed in the programmable layout region, so that the tunnel wire 86 is located under the metal wire 85 and does not occupy the space of the programmable layout region.

In summary, since the present invention adopts such an architecture that the programmable layout region takes advantage of the tunnel wire disposed in the fixed body region for propagating electrical signals, therefore the present invention is able to reduce cost and the routing resource in the programmable layout region reserved for a customer's user end to tailor, simplify the circuit connection scheme and improve the routability of a chip.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A structured ASIC layout architecture having tunnel wires, comprising:
a fixed body region, adopted for providing a function capability or multiple function capability, comprising a tunnel wire or multiple tunnel wires to provide reserve interconnection paths; and
a programmable layout region, disposed over the fixed body region, connected to the fixed body region, wherein the programmable layout region is connected to the tunnel wire of the fixed body region for starting up the reserve interconnection paths to propagate an electrical signal.

2. The structured ASIC layout architecture having tunnel wires as recited in claim 1, wherein the tunnel wire comprises a first metal layer, the programmable layout region comprises a programmable via layer and the programmable layout region is connected to the metal layer of the tunnel wire through the programmable via layer.

3. The structured ASIC layout architecture having tunnel wires as recited in claim 1, wherein the tunnel wire comprises a second metal layer and a via layer, the programmable layout region comprises a programmable metal layer and the programmable layout region is connected to the via layer of the tunnel wire through the programmable metal layer.

4. The structured ASIC layout architecture having tunnel wires as recited in claim 1, wherein the tunnel wire of the fixed body region is isolated from other devices of the fixed body region.

5. The structured ASIC layout architecture having tunnel wires as recited in claim 1, wherein the tunnel wire comprises a linear shape.

6. A structured ASIC layout architecture having tunnel wires, comprising:
a fixed body region, adopted for providing a function capability or multiple function capability, comprising a tunnel wire or multiple tunnel wires and multiple transistors to provide reserve interconnection paths; and
a programmable layout region, disposed over the fixed body region, for connected to the fixed body region, wherein the programmable layout region is connected to the tunnel wire of the fixed body region for starting up the reserve interconnection paths and allow the transistors to propagate an electrical signal by using the spare interconnection paths.

7. The structured ASIC layout architecture having tunnel wires as recited in claim 6, wherein the tunnel wire comprises a first metal layer, the programmable layout region comprises a programmable via layer and the programmable layout region is connected to the metal layer of the tunnel wire through the programmable via layer.

8. The structured ASIC layout architecture having tunnel wires as recited in claim 6, wherein the tunnel wire comprises a second metal layer and a via layer, the programmable layout region comprises a programmable metal layer and the programmable layout region is connected to the via layer of the tunnel wire through the programmable metal layer.

9. The structured ASIC layout architecture having tunnel wires as recited in claim 6, wherein the tunnel wire of the fixed body region is isolated from other devices of the fixed body region.

10. The structured ASIC layout architecture having tunnel wires as recited in claim 6, wherein the tunnel wire comprises a linear shape.

11. The structured ASIC layout architecture having tunnel wires as recited in claim 6, wherein the transistor is a MOS transistor.
